(19) United States
(12) Patent Application Publication
(10) Pub. No.: US 2026/0033165 A1
(43) Pub. Date: Jan. 29, 2026

(54) DISPLAY PANEL, MANUFACTURING METHOD THEREOF, AND DISPLAY DEVICE

(71) Applicant: HKC CORPORATION LIMITED, SHENZHEN (CN)

(72) Inventors: Yao LI, SHENZHEN (CN); Lidan YE, SHENZHEN (CN)

(73) Assignee: HKC CORPORATION LIMITED, SHENZHEN (CN)

(21) Appl. No.: 19/254,009

(22) Filed: Jun. 30, 2025

(30) Foreign Application Priority Data
Jul. 23, 2024 (CN) 202410994931.1

(51) Int. Cl. H10K 59/124; H10K 59/12

(52) U.S. Cl. CPC H10K 59/124; H10K 59/1201

(57) ABSTRACT

The present application provides a display panel, a manufacturing method thereof, and a display device. The display panel includes a silicon-based driving plate, a glass substrate, a dielectric layer, and an organic light-emitting display component. The glass substrate is arranged on a side of the silicon-based driving plate and has a first through-hole defined therein. The dielectric layer is arranged between the silicon-based driving plate and the glass substrate and has a second through-hole defined therein. A size of an opening on a side of the second through-hole facing the silicon-based driving plate is greater than a size of another opening on another side of the second through-hole. The organic light-emitting display component is arranged on a side of the glass substrate away from the silicon-based driving plate, and is bonded to the silicon-based driving plate through a connecting portion filled in the first through-hole and the second through-hole.

### CROSS REFERENCE TO RELATED APPLICATIONS

The present disclosure claims priority to Chinese Patent Application No. 202410994931.1, filed Jul. 23, 2024, the entire contents of which are incorporated herein by reference.

### TECHNICAL FIELD

The present disclosure relates to the field of display technologies, and in particular to a display panel, a manufacturing method of a display panel, and a display device.

### BACKGROUND

Virtual Reality (VR) is a technology based on computer technology. By using and integrating the latest achievements in multiple high-tech fields, such as three-dimensional graphics technology, multimedia technology, simulation technology, display technology, and servo technology, and with the help of devices such as computers, the VR generates a realistic virtual world with multiple sensory experiences such as three-dimensional visual, tactile, and olfactory, allowing people in the virtual world to have an immersive feeling.

Augmented Reality (AR) is a technology that skillfully integrates virtual information with the real world and widely uses multiple technical means such as multimedia, three-dimensional modeling, real-time tracking and registration, intelligent interaction, and sensing. After simulated, virtual information such as text, images, three-dimensional models, music, and videos. generated by a computer is applied to the real world. Two kinds of information complement each other, thus realizing “enhancement” of the real world.

Silicon-based organic light-emitting display (OLED) is a type of display device that is currently applied to the AR/VR field and has the best performance. When compared with conventional active-matrix organic light-emitting diode (AMOLED) devices which use amorphous silicon, micro-silicon, or low-temperature poly-silicon thin-film transistors as the backplane, a single-crystal silicon backplane has a higher carrier mobility. The single-crystal silicon backplane is an active organic light-emitting diode display device manufactured with complementary metal oxide semiconductor (CMOS) devices as a driving unit, and a traditional externally bonded display chip is integrated in the silicon-based backplane.

In the manufacturing process, by evaporating a pixel pattern isolation layer and subsequently an anode, an OLED device, and a cathode on a driving substrate formed with a silicon-based CMOS, a smaller pixel size may be obtained and pixel refinement may be achieved. The pixel size is usually 6 μm-15 μm, which is 1/10 or even smaller than that of traditional display devices, and the pixel density is more than 10 times that of traditional devices. This results in a display fineness beyond the retinal level, with advantages such as high resolution, high integration, low power consumption, small size, and light weight, and wide application in military markets such as head-mounted helmets, gun sights, and night vision devices. However, during the evaporation of the organic layer, the silicon-based driving circuit is likely to be affected, resulting in the failure of the driving circuit and an increase in cost.

### SUMMARY OF THE DISCLOSURE

A technical solution adopted by the present disclosure is to provide a display panel. The display panel includes a silicon-based driving plate, a glass substrate, a dielectric layer, and an organic light-emitting display component. The glass substrate is arranged on a side of the silicon-based driving plate and has a first through-hole defined therein. The dielectric layer is arranged between the silicon-based driving plate and the glass substrate and has a second through-hole defined therein. A size of an opening on a side of the second through-hole facing the silicon-based driving plate is greater than a size of another opening on another side of the second through-hole facing the glass substrate. The organic light-emitting display component is arranged on a side of the glass substrate away from the silicon-based driving plate. The organic light-emitting display component is bonded to the silicon-based driving plate through a connecting portion filled in the first through-hole and the second through-hole.

Another technical solution adopted by the present disclosure is to provide a manufacturing method of a display panel. The method includes steps of: providing a silicon-based driving plate and a glass substrate, a side of the silicon-based driving plate being arranged with an electrode bump and the glass substrate being defined with a first through-hole; forming a dielectric layer covering the electrode bump on the silicon-based driving plate and forming a second through-hole on the dielectric layer to expose the electrode bump, a size of an opening on a side of the second through-hole away from the silicon-based driving plate being greater than a size of another opening on another side of the second through-hole facing the silicon-based driving plate; bonding the glass substrate to the dielectric layer so that the first through-hole and the second through-hole are communicated; filling a connecting portion in the first through-hole and the second through-hole; forming an organic light-emitting display component on the glass substrate, the organic light-emitting display component being bonded to the silicon-based driving plate through the connecting portion and the electrode bump.

Further another technical solution adopted by the present disclosure is to provide a display device including a display panel and a power supply configured for supplying power to the display panel. The display panel is a display panel according to any one of embodiments above, or the display panel is a display panel manufactured by a manufacturing method of a display panel according to any one of embodiments above.

### BRIEF DESCRIPTION OF THE DRAWINGS

In order to more clearly illustrate the technical solutions in the embodiments of the present disclosure, the drawings needed to be used in the embodiments are briefly introduced below. Obviously, the drawings in the following description are only some embodiments of the present disclosure. For those skilled in the art, other drawings may also be obtained according to these drawings without any creative efforts.

FIG. 1 is a first schematic structural view of a display panel according to some embodiments of the present disclosure.

FIG. 2 is a schematic view of a process of laser-induced denaturation etching according to some embodiments of the present disclosure.

FIG. 3 is a first schematic structural view of an organic light-emitting display component of a display panel according to some embodiments of the present disclosure.

FIG. 4 is a schematic structural view of a dielectric layer of a display panel according to some embodiments of the present disclosure.

FIG. 5 is a second schematic structural view of a display panel according to some embodiments of the present disclosure.

FIG. 6 (a) is a first schematic structural view of region G shown in FIG. 5.

FIG. 6 (b) is a second schematic structural view of region G shown in FIG. 5.

FIG. 6 (c) is a third schematic structural view of region G shown in FIG. 5.

FIG. 7 is a third schematic structural view of a display panel according to some embodiments of the present disclosure.

FIG. 8 is a fourth schematic structural view of a display panel according to some embodiments of the present disclosure.

FIG. 9 is a fifth schematic structural view of a display panel according to some embodiments of the present disclosure.

FIG. 10 is a sixth schematic structural view of a display panel according to some embodiments of the present disclosure.

FIG. 11 is a schematic structural view of a silicon-based driving plate of a display panel according to some embodiments of the present disclosure.

FIG. 12 is a second schematic structural view of an organic light-emitting display component of a display panel according to some embodiments of the present disclosure.

FIG. 13 is a schematic flow chart of a manufacturing method of a display panel according to some embodiments of the present disclosure.

FIG. 14 is a schematic flow chart of block S10 shown in FIG. 13.

FIG. 15 (a) is a schematic structural view corresponding to block S11 shown in FIG. 14.

FIG. 15 (b) is a schematic structural view corresponding to block S12 shown in FIG. 14.

FIG. 15 (c) is a schematic structural view corresponding to block S13 shown in FIG. 14.

FIG. 15 (d) is a schematic structural view corresponding to block S14 shown in FIG. 14.

FIG. 16 is a schematic flow chart of block S20 shown in FIG. 13.

FIG. 17 (a) is a schematic structural view corresponding to block S21 shown in FIG. 16.

FIG. 17 (b) is a schematic structural view corresponding to block S22 shown in FIG. 16.

FIG. 17 (c) is a schematic structural view corresponding to block S23 shown in FIG. 16.

FIG. 17 (d) is a schematic structural view corresponding to block S24 shown in FIG. 16.

FIG. 17 (e) is a schematic structural view corresponding to block S25 shown in FIG. 16.

FIG. 17 (f) is a schematic structural view corresponding to block S26 shown in FIG. 16.

FIG. 18 is a schematic structural view of a display device according to some embodiments of the present disclosure.

### REFERENCE LABELS OF THE DRAWINGS

display panel 100; silicon-based driving plate 10; silicon substrate 11; driving component 12; driving chip wafer 12a; protective layer 13; glass substrate 20; dielectric layer 30; first inorganic insulating layer 31; organic insulating layer 32; second inorganic insulating layer 33; organic light-emitting display component 40; anode 41; light-emitting layer 42; cathode 43; pixel defining layer 44; isolation structure 45; sub-pixel 46; first electrode 461; light-emitting component 462; second electrode 463; encapsulating layer 47; connecting portion 50; electrode bump 60; first through-hole A; second through-hole B; first sub-through-hole B1; second sub-through-hole B2; third sub-through-hole B3.

### DETAILED DESCRIPTION

The technical solutions in the embodiments of the present disclosure are described clearly and completely below in conjunction with the accompanying drawings in the embodiments of the present disclosure. It is understood that the specific embodiments described herein are used only to illustrate the present disclosure, and cannot be used to limit the present disclosure. It should also be noted that, for the sake of description, only some but not all of the structures related to the present disclosure are shown in the drawings. Based on the embodiments in the present disclosure, all other embodiments obtained by those skilled in the art without creative work fall within the scope of protection of the present disclosure.

In the present disclosure, the terms “first”, “second”, and etc. are merely used to distinguish different objects, and are not used to describe a particular order. In additions, the terms “comprise” and “include”, as well as any variations thereof, are intended to cover non-exclusive inclusions. For example, a process, method, system, product, or device that contains a series of steps or units is not limited to a listed step or unit, but may optionally include a step or unit that is not listed, or may optionally include other steps or units that are inherent to the process, method, product, or device.

The term “embodiment” mentioned in the specification means that particular features, structures, or characteristics described in conjunction with the embodiments may be included in at least one embodiment of the present disclosure. This term appearing in various positions in the specification does not necessarily refer to a same embodiment, nor is it an independent or alternative embodiment mutually exclusive with other embodiments. Those skilled in the art explicitly or implicitly understand that the embodiments described in the specification may be combined with other embodiments.

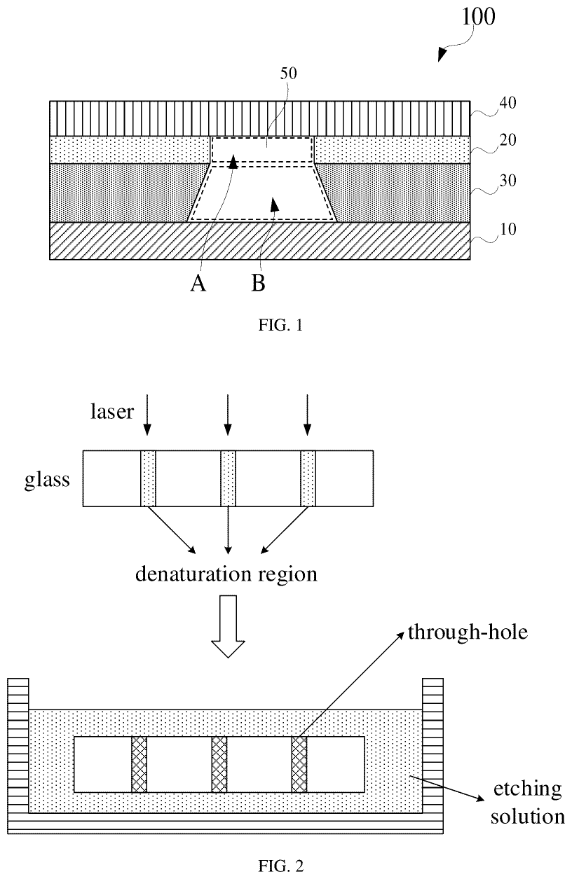

As shown in FIG. 1, FIG. 1 is a first schematic structural view of a display panel according to some embodiments of the present disclosure. The display panel 100 includes a silicon-based driving plate 10, a glass substrate 20, a dielectric layer 30, and an organic light-emitting display component 40.

The glass substrate 20 is arranged on a side of the silicon-based driving plate 10, and the glass substrate 20 is defined with a first through-hole A. The dielectric layer 30 is arranged between the silicon-based driving plate 10 and the glass substrate 20, and the dielectric layer 30 is defined with a second through-hole B. A size of an opening on a side of the second through-hole B facing the silicon-based driving plate 10 is greater than a size of another opening on another side of the second through-hole B facing the glass substrate 20. The organic light-emitting display component 40 is arranged on a side of the glass substrate 20 away from the silicon-based driving plate 10. The organic light-emitting display component 40 is bonded to the silicon-based driving plate 10 through a connecting portion 50 filled in the first through-hole A and the second through-hole B. That is, the silicon-based driving plate 10 and the organic light-emitting display component 40 are respectively arranged on opposite two sides of the glass substrate 20. The first through-hole A and the second through-hole B are approximate regions where dashed frames are located as shown in the drawings.

The first through-hole A on the glass substrate 20 may be formed by through glass via (TGV) process. TGV refers to a process of making vertical electrical interconnection through the glass substrate 20.

In a traditional process, through silicon via (TSV) process is generally adopted. Both TSV and TGV are applied in the field of 2.5D or 3D interposers, but TSV has two main problems: 1) the high cost, a TSV production adopts a silicon etching process, and a silicon through-hole requires oxidation of an insulation layer, thin wafer holding and other technologies; 2) poor electrical performance, silicon material belongs to semiconductor materials, when a transmission line transmits signals, the signals and the material of the substrate have a strong electromagnetic coupling effect, and an eddy current phenomenon occurs in the substrate, resulting in poor signal integrity (e.g., insertion loss, crosstalk, etc.). However, the TGV process has advantages as follows.
1) Excellent high-frequency electrical characteristics. Glass material is an insulator material, a dielectric constant thereof is only about ⅓ of the silicon material, and a loss factor thereof is 2-3 orders of magnitude lower than that of silicon material, which greatly reduces the substrate loss and parasitic effect and ensures the integrity of the transmission signal.
2) Large-size ultra-thin glass substrate is easy to obtain. At present, ultra-large (e.g., the length is greater than 2 meters and the width is greater than 2 meters) and ultra-thin (e.g., the thickness is less than 50 μm) panel glass and ultra-thin flexible glass materials can be provided.
3) Low cost. Benefiting from the easy availability of large-size ultra-thin panel glass and the fact that there is no need to deposit insulation, the production cost of glass interposers is only about ⅛ that of silicon-based interposers.
4) The process flow is simple. There is no need to deposit insulation on a surface of the substrate and on an inner wall of the TGV, and there is no need for thinning in the ultra-thin interposer.
5) Strong mechanical stability. Even when the thickness of the interposer is less than 100 μm, the warpage is still relatively small.
6) Wide range of applications. In addition to having a good application prospect in the field of high frequency, as a transparent material, the glass substrate may also be applied in the field of optoelectronic system integration. The advantages of air tightness and corrosion resistance make the glass substrate have great potential in the field of micro-electro-mechanical system (MEMS) encapsulating.

In the process of forming the first through-hole A based on the TGV process, the common methods include mechanical drilling, dry etching, wet etching, focused ion beam, laser ablation and laser-induced denaturation, etc. Laser ablation and laser-induced denaturation are illustrated as follows.

Laser ablation means that after laser excitation, glass-based atoms oscillate at high frequency and are rapidly heated, and the atoms detached from the substrate and are ablated and volatilized. Melt products and residues caused by laser ablation adhere to openings of deep holes, and surface residues need to be removed after the etching is complete.

Laser-induced denaturation etching means that an ultrashort pulse laser (i.e., the wavelength is in the picosecond range) induces the glass to generate a continuous denaturation region. Denatured glass has a faster etching rate in hydrofluoric acid compared to glass in the undenatured region. The process does not create cracks in the glass and allows for the creation of blind-holes and through-holes in the glass. Advanced laser-induced etching technology is able to manufacture high aspect ratio structures. At present, the typical TGV pore size is 20 μm to 100 μm, and the aspect ratio is 1:4 to 1:10.

As shown in FIG. 2, FIG. 2 is a schematic view of a process of laser-induced denaturation etching according to some embodiments of the present disclosure. Laser-induced denaturation etching mainly includes two processes as follows.

First, an ultrashort pulse laser is used to create denatured regions on the glass.

Second, the laser-treated glass is etched in a hydrofluoric acid solution.

In the above embodiments, the silicon-based driving plate 10 may be called a silicon-based complementary metal oxide semiconductor (CMOS) driver substrate. The silicon-based driving plate 10 includes a silicon substrate and a driving circuit made on the silicon substrate. The driving circuit is manufactured by CMOS integrated circuit process, and characteristic size of transistor thereof is 0.6 microns, 0.5 microns, 0.35 microns, 0.25 microns, 0.18 microns, 0.13 microns, or other typical deep sub-micron process sizes. The driving circuit supports dual voltage or multi-voltage regions, the voltage range of the analog circuit is from −5V to +5V, and the voltage range of the digital circuit is from +1V to +5V.

In some embodiments, the driver circuit is formed on the silicon substrate to form a driving chip wafer. The driving chip wafer is cut into wafer slices, and a wafer slice corresponds to a sub-pixel.

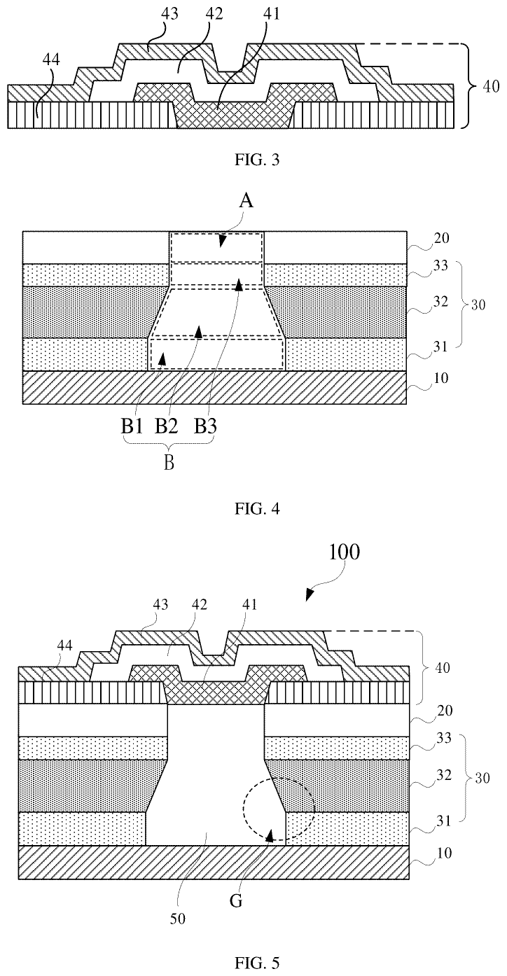

In the above embodiments, the organic light-emitting display component 40 is an OLED component. As shown in FIG. 3, FIG. 3 is a first schematic structural view of an organic light-emitting display component of a display panel according to some embodiments of the present disclosure. The structure of the organic light-emitting display component 40 includes an anode 41, a light-emitting layer 42, a cathode 43, and a pixel defining layer 44. The silicon-based driving plate 10 being bonded with the organic light-emitting display component 40 means that the anode and/or cathode being connected with the above-mentioned driving circuit (e.g., wafer slices) through the first through-hole A on the glass substrate 20 and the second through-hole B on the dielectric layer 30.

In some embodiments, as shown in FIG. 4, FIG. 4 is a schematic structural view of a dielectric layer of a display panel according to some embodiments of the present disclosure. The dielectric layer 30 includes a first inorganic insulating layer 31, an organic insulating layer 32, and a second inorganic insulating layer 33. The arrangement relationship is as follows. The first inorganic insulating layer 31 is arranged on a side of the silicon-based driving plate 10 facing the glass substrate 20, and the first inorganic insulating layer 31 is defined with a first sub-through-hole B1. The organic insulating layer 32 is arranged on a side of the first inorganic insulating layer 31 facing the glass substrate 20, and the organic insulating layer 32 is defined with a second sub-through-hole B2. The second inorganic insulating layer 33 is arranged on a side of the organic insulating layer 32 facing the glass substrate 20, and the second inorganic insulating layer 33 is defined with a third sub-through-hole B3. The first sub-through-hole B1, the second sub-through-hole B2, and the third sub-through-hole B3 are communicated in sequence to form the second through-hole B.

In some embodiments, the organic insulating layer 32 may be set into a complex irregular-shaped structure by means of nanoimprinting. In some embodiments, the materials of the first inorganic insulating layer 31 and the second inorganic insulating layer 33 may include, but are not limited to, materials such as SiNO, SiNx, SiO₂, or SixNO. In some embodiments, the material of the organic insulating layer 32 may include, but is not limited to, acrylic-type organic polymer materials.

Nanoimprint lithography completes the transfer of patterns through contact imprinting, which is equivalent to the exposure and development processed in optical lithography technology, and uses an etching transfer process to transfer the structure to other materials. The nanoimprint lithography overcomes the problem of the resolution limit caused by the optical diffraction phenomenon in optical lithography technology, and demonstrates unique advantages of ultra-high resolution, high efficiency, low cost, and suitability for industrial production. The latest overlay accuracy of nanoimprint lithography (NIL) has reached a circuit wire width of 5 nm. At present, three common nanoimprint technologies are hot embossing, ultraviolet imprinting, and compression molding. In this proposal, taking the hot embossing technology as an example, the preparation process of the isolation column will be illustrated. The imprinting material is a resin with high light transmittance, which is a common PDL organic resin.

In some embodiments, as shown in FIG. 5, FIG. 5 is a second schematic structural view of a display panel according to some embodiments of the present disclosure. In the structure of the display panel 100, a contact surface between the organic insulating layer 32 and the first inorganic insulating layer 31 is defined as a reference plane. An inner sidewall of the second sub-through-hole B2 is obliquely arranged with the reference plane, so that a size of an opening on a side of the second sub-through-hole B2 of the organic insulating layer 32 facing the first inorganic insulating layer 31 is greater than a size of another opening on another side of the second sub-through-hole B2 facing the second inorganic insulating layer 33.

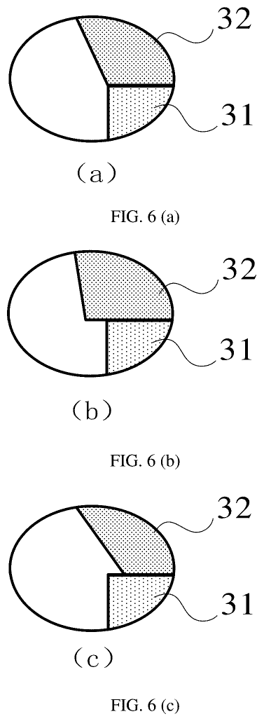

Further, as shown in FIG. 6 (a) to FIG. 6 (c), FIG. 6 (a) to FIG. 6 (c) are schematic structural views of region G shown in FIG. 5. In some embodiments, on the contact surface between the organic insulating layer 32 and the first inorganic insulating layer 31, i.e., on the reference plane, as shown in FIG. 6 (a), a length of the organic insulating layer 32 on the reference plane is equal to that of the first inorganic insulating layer 31, or as shown in FIG. 6 (b), the length of the organic insulating layer 32 on the reference plane is greater than that of the first inorganic insulating layer 31, or as shown in FIG. 6 (c), the length of the organic insulating layer 32 on the reference plane is less than that of the first inorganic insulating layer 31.

In some embodiments, a height of the organic insulating layer 32 is set to 1 μm to 2 μm. The height may be specifically set according to actual situations or schemes. In some embodiments, a diameter of the opening on the side of the second sub-through-hole B2 facing the glass substrate 20 is equal to a diameter of the first through-hole A, or slightly less than the diameter of the first through-hole A. In some embodiments, a diameter of the third sub-through-hole B3 is equal to the diameter of the first through-hole A, and the diameter of the third sub-through-hole B3 is greater than or equal to the diameter of the opening on the side of the second sub-through-hole B2 facing the glass substrate 20. In this way, the absence of an organic insulating layer 32 below the second inorganic insulating layer 33 is prevented, and the organic insulating layer 32 may play a supporting role for the second inorganic insulating layer 33. In some embodiments, a height of the second inorganic insulating layer 33 is set to 0.2 μm to 0.5 μm. The height may be specifically set according to actual situations or schemes.

In some embodiments, as shown in FIG. 5 and FIG. 6 (a) to FIG. 6 (c), an angle between the inner sidewall of the second sub-through-hole B2 and the reference plane is in a range of 30 degrees to 75 degrees. The angle may be specifically set according to actual situations or schemes.

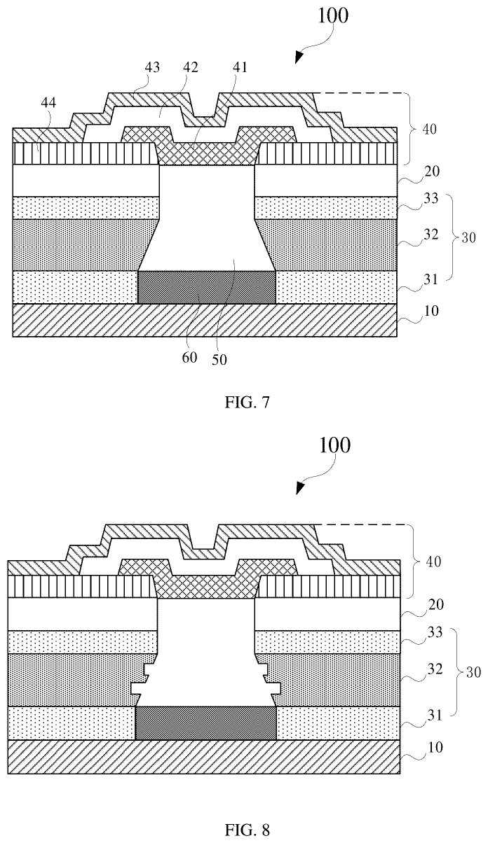

In some embodiments, as shown in FIG. 7, FIG. 7 is a third schematic structural view of a display panel according to some embodiments of the present disclosure. An electrode bump 60 is arranged on the side of the silicon-based driving plate 10 facing the glass substrate 20. The electrode bump 60 is accommodated in the first sub-through-hole B1. The organic light-emitting display component 40 is bonded to the silicon-based driving plate 10 through a connecting portion 50 filled in the first through-hole A, the second sub-through-hole B2, and the third sub-through-hole B3, and the electrode bump 60.

In some embodiments, as shown in FIG. 7, the first inorganic insulating layer 31 is designed to be aligned with the electrode bump 60 or slightly wrap a convex edge of the electrode bump 60. The height of the first inorganic insulating layer 31 may be equal to or slightly greater than a protrusion height of the electrode bump 60.

In some embodiments, a recessed portion is defined on the inner sidewall of the second sub-through-hole B2, a protruding portion is arranged on an outer sidewall of the connecting portion 50, and the protruding portion is embedded in the recessed portion.

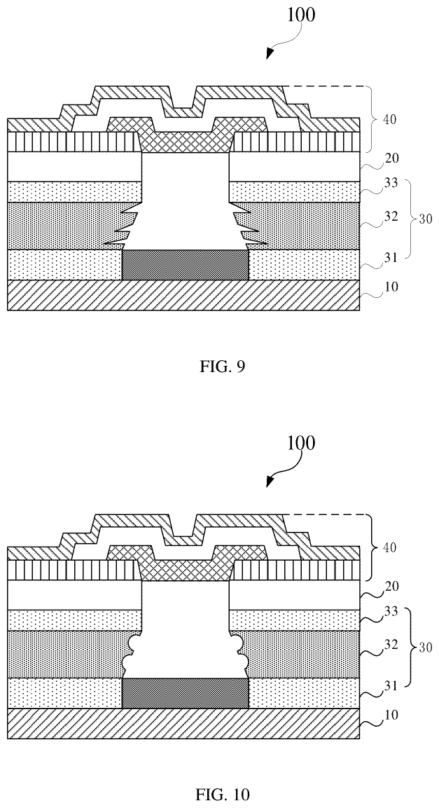

As shown in FIG. 8, FIG. 9, and FIG. 10, FIG. 8 is a fourth schematic structural view of a display panel according to some embodiments of the present disclosure, FIG. 9 is a fifth schematic structural view of a display panel according to some embodiments of the present disclosure, and FIG. 10 is a sixth schematic structural view of a display panel according to some embodiments of the present disclosure. The above embodiments are scheme designs made for shapes and quantities of the recessed portion on the inner sidewall of the second sub-through-hole B2 and the protruding portion on the outer sidewall of the connecting portion 50. Specifically, the irregular shapes and quantities of the recessed portion and the protruding portion, whether the designs of the irregular shapes are smooth inverted triangles, rectangular serrations, triangular serrations, circular serrations, or other shapes, are all intended to increase a surface contact area. Therefore, there is no fixed shape, and it is not limited to the scheme setting of the above embodiments. The shapes and quantities may be specifically set according to actual situations or schemes, and are not specifically limited herein.

The silicon-based driving plate 10 and the organic light-emitting display component 40 are introduced below, respectively.

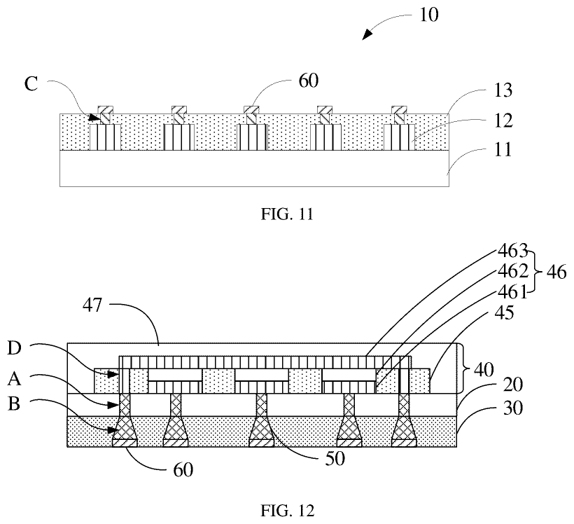

As shown in FIG. 11, FIG. 11 is a schematic structural view of a silicon-based driving plate of a display panel according to some embodiments of the present disclosure. The silicon-based driving plate 10 includes a silicon substrate 11, multiple driving components 12, and a protective layer 13.

The driving components 12 are arranged on a side of the silicon substrate 11 facing the glass substrate 20. The protective layer 13 covers the driving components 12. The protective layer 13 is defined with multiple third through-holes C. The electrode bump 60 is connected to a corresponding driving component 12 of the multiple driving components 12 through a corresponding third through-hole C of the multiple third through-holes C.

The driving components 12 are CMOS components. Specifically, a driving circuit is manufactured on the silicon substrate 11 to form a driving chip wafer. The driving chip wafer is cut to form the multiple driving components 12.

A mask etching process may be used to form the third through-holes C on the protective layer 13. A conductive material may be deposited on the protective layer 13 to form a conductive layer. The conductive material is filled into the third through-holes C. A mask etching process may be applied to the conductive layer to form multiple electrode bumps 60, each corresponding to a driving component 12.

As shown in FIG. 12, FIG. 12 is a second schematic structural view of an organic light-emitting display component of a display panel according to some embodiments of the present disclosure. The organic light-emitting display component 40 includes an isolation structure 45, multiple sub-pixels 46, and an encapsulating layer 47.

The isolation structure 45 is arranged on a side of the glass substrate 20 away from the silicon-based driving plate 10. The isolation structure 45 is defined with multiple pixel openings. Each of the multiple sub-pixels 46 is arranged in a corresponding one of the multiple pixel openings. Understandably, the isolation structure 45 is configured to define positions of the sub-pixels. The isolation structure 45 may include a pixel-limiting layer on a lower layer and an isolation portion on an upper layer.

A number of the electrode bump 60 is more than one, a number of the first through-hole A is more than one, and a number of the second through-hole B is more than one. Each of the sub-pixels 46 includes a first electrode 461, a light-emitting component 462, and a second electrode 463. The first electrode 461 is arranged on the side of the glass substrate 20 away from the silicon-based driving plate 10. The first electrode 461 is connected with a corresponding electrode bump 60 through a corresponding first through-hole A. The light-emitting component 462 is arranged on a side of the first electrode 461 away from the glass substrate 20. The second electrode 463 is arranged on a side of the light-emitting component 462 away from the first electrode 461. The second electrode 463 is connected to at least one electrode bump 60 through at least one first through-hole A and at least one second through-hole B.

The first electrode 461 is an anode, and the second electrode 463 is a cathode. The first electrode 461 and the second electrode 463 are made of titanium, aluminum, copper, etc. Considering that light emits from a side of the organic light-emitting display component 40, the electrodes on the corresponding side may adopt conductive polymer, indium tin oxidation (ITO), etc.

The isolation structure 45 is defined with multiple fourth through-holes D. Each of the fourth through-holes D is communicated with a corresponding first through-hole A. The second electrode 463 is connected with a corresponding electrode bump 60 through a corresponding fourth through-hole D, the corresponding first through-hole A, and the corresponding second through-hole B.

Taking the RGB three-color pixel as an example, a width of a portion of the isolation structure between any two of three sub-pixels in the same pixel is relatively small, and a width of another portion of the isolation structure between two adjacent pixels is relatively large. The fourth through-holes D may be formed in the another portion of the isolation structure between the two adjacent pixels, so that a connection of the first electrode 461, the second electrode 463, the connecting portion 50, and the electrode bump 60 is realized.

The silicon-based driving plate 10 and the glass substrate 20 need to achieve signal transmission through the contact connection of conductive materials inside the holes. During the two substrates are attached and display, since the overall structure includes two portions, if deformation occurs under external force, the two portions are prone to relative displacement. This is more obvious for large-sized display substrates. At this time, the conductive materials in the through holes are easily pulled by the external force, causing the film layer to break or be damaged. Over time, this will lead to connection failure, a decrease in the display effect or abnormal display, and a reduction in the service life of the device.

Therefore, the present disclosure provides the display panel 100 for the structural design of improving the connection stability of the through-hole in the structure to solve the above problems.

The display panel 100 provided in the embodiments includes the silicon-based driving plate 10, the glass substrate 20, the dielectric layer 30, and the organic light-emitting display component 40. The glass substrate 20 is arranged on the side of the silicon-based driving plate 10, and the glass substrate 20 is defined with the first through-hole A. The dielectric layer 30 is arranged between the silicon-based driving plate 10 and the glass substrate 20, and the dielectric layer 30 is defined with the second through-hole B. The size of the opening on the side of the second through-hole B facing the silicon-based driving plate 10 is greater than the size of the another opening on the another side of the second through-hole B facing the glass substrate 20. The organic light-emitting display component 40 is arranged on the side of the glass substrate 20 away from the silicon-based driving plate 10. The organic light-emitting display component 40 is bonded to the silicon-based driving plate 10 through the connecting portion 50 filled in the first through-hole A and the second through-hole B. In this way, on the one hand, by arranging the dielectric layer 30 and setting an inner portion of the organic insulating layer 32 in the middle of the dielectric layer 30 to an irregular-shaped structure, a surface area inside the organic insulating layer 32 is increased; on the other hand, by filling a conductive material in the first through-hole A and the second through-hole B, the organic light-emitting display component 40 is bonded to the silicon-based driving plate 10, and a contact area with a film layer of the lower silicon-based driving plate 10 is increased. Furthermore, if relative displacement occurs between the silicon-based driving plate 10 and the glass substrate 20, the conductive material bonding the silicon-based driving plate 10 and the glass substrate 20 may experience increased frictional resistance due to its interlocking fit with the irregular-shaped structure. This effectively prevents displacement and deformation of the conductive material, as well as issues such as film layer fracture and delamination caused by external forces. In this way, potential connection failures may be prevented if the two-layer structure of the silicon-based driving plate 10 and the glass substrate 20 undergoes deformation, thereby significantly improving the stability of signal transmission through the through-holes.

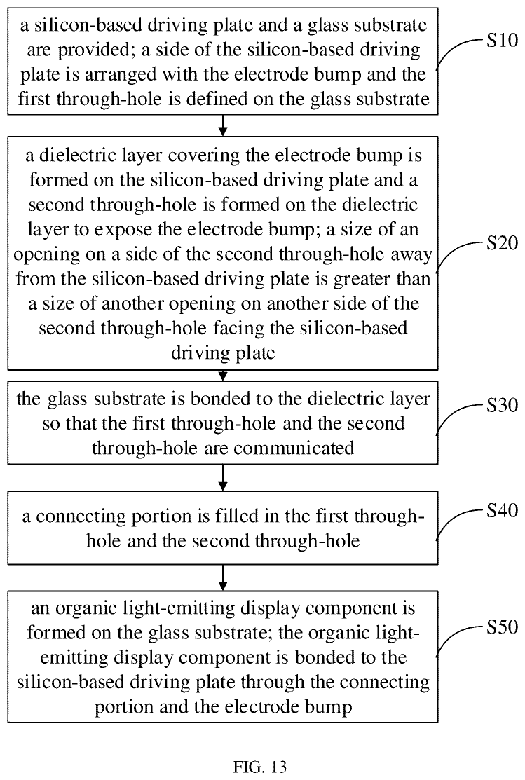

As shown in FIG. 13, FIG. 13 is a schematic flow chart of a manufacturing method of a display panel according to some embodiments of the present disclosure. The manufacturing method of the display panel 100 may include operations executed by the following blocks.

At block S10, a silicon-based driving plate 10 and a glass substrate 20 are provided. A side of the silicon-based driving plate 10 is arranged with the electrode bump 60 and the first through-hole A is defined on the glass substrate 20.

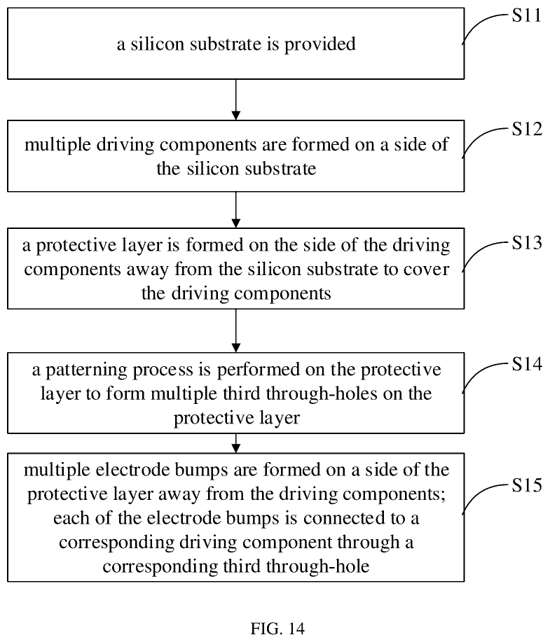

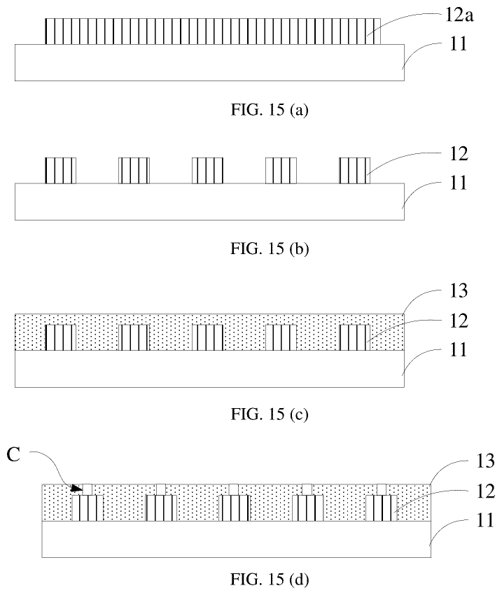

As shown in FIG. 14 and FIG. 15 (a) to FIG. 15 (d), FIG. 14 is a schematic flow chart of block S10 shown in FIG. 13, and FIG. 15 (a) to FIG. 15 (d) are schematic structural views corresponding to each block shown in FIG. 14. The silicon-based driving plate 10 may be manufactured by the following process.

At block S11, a silicon substrate is provided.

The silicon substrate is single-crystal silicon.

At block S12, multiple driving components are formed on a side of the silicon substrate.

The driving component is a CMOS component.

In some embodiments, as shown in FIG. 15 (a) and FIG. 15 (b), FIG. 15 (a) to FIG. 15 (d) are schematic structural views corresponding to each block shown in FIG. 14. FIG. 15 (b) is a second schematic structural view of a structure corresponding to block S12 according to some embodiments. A driving circuit is manufactured on the silicon substrate 11 to form a driving chip wafer 12a. The driving chip wafer 12a is cut into wafer slices, which are the driving components 12.

At block S13, a protective layer is formed on the side of the driving components away from the silicon substrate to cover the driving components.

As shown in FIG. 15 (c), FIG. 15 (c) is a schematic structural view of a structure corresponding to block S13 according to some embodiments. The protective layer 13 covers the driving components 12 and exposed portions of the silicon substrate 11.

At block S14, a patterning process is performed on the protective layer to form multiple third through-holes on the protective layer.

As shown in FIG. 15 (d), FIG. 15 (d) is a schematic structural view of a structure corresponding to block S14 in some embodiments. The patterning process is performed on the protective layer 13 to form the third through-holes C on the protective layer 13.

At block S15, multiple electrode bumps 60 are formed on a side of the protective layer away from the driving components. Each of the electrode bumps 60 is connected to a corresponding driving component through a corresponding third through-hole.

As shown in FIG. 11, the electrode bumps 60 are formed on the side of the protective layer 13 away from the driving components 12. Each of the electrode bumps 60 is connected to the corresponding driving component 12 through the corresponding third through-hole C.

In block S10, the TGV process is generally adopted. In the process of forming the first through-hole A based on the TGV process, the common methods include mechanical drilling, dry etching, wet etching, focused ion beam, laser ablation and laser-induced denaturation, etc. Laser ablation and laser-induced denaturation are illustrated as follows.

Laser ablation means that after laser excitation, glass-based atoms oscillate at high frequency and are rapidly heated, and the atoms detached from the substrate and are ablated and volatilized. Melt products and residues caused by laser ablation adhere to openings of deep holes, and surface residues need to be removed after the etching is complete.

Laser-induced denaturation etching means that an ultrashort pulse laser (i.e., the wavelength is in the picosecond range) induces the glass to generate a continuous denaturation region. Denatured glass has a faster etching rate in hydrofluoric acid compared to glass in the undenatured region. The process does not create cracks in the glass and allows for the creation of blind-holes and through-holes in the glass. Advanced laser-induced etching technology is able to manufacture high aspect ratio structures. At present, the typical TGV pore size is 20 μm to 100 μm, and the aspect ratio is 1:4 to 1:10.

As shown in FIG. 2, FIG. 2 is a schematic view of a process of laser-induced denaturation etching according to some embodiments of the present disclosure. Laser-induced denaturation etching mainly includes two processes as follows.

First, an ultrashort pulse laser is used to create denatured regions on the glass.

Second, the laser-treated glass is etched in a hydrofluoric acid solution.

In the above embodiments, the silicon-based driving plate 10 may be called a silicon-based complementary metal oxide semiconductor (CMOS) driver substrate. The silicon-based driving plate 10 includes a silicon substrate and a driving circuit made on the silicon substrate. The driving circuit is manufactured by CMOS integrated circuit process, and characteristic size of transistor thereof is 0.6 microns, 0.5 microns, 0.35 microns, 0.25 microns, 0.18 microns, 0.13 microns, or other typical deep sub-micron process sizes. The driving circuit supports dual voltage or multi-voltage regions, the voltage range of the analog circuit is from −5V to +5V, and the voltage range of the digital circuit is from +1V to +5V.

At block S20, a dielectric layer 30 covering the electrode bump 60 is formed on the silicon-based driving plate 10 and a second through-hole B is formed on the dielectric layer 30 to expose the electrode bump 60. A size of an opening on a side of the second through-hole B away from the silicon-based driving plate 10 is greater than a size of another opening on another side of the second through-hole B facing the silicon-based driving plate 10.

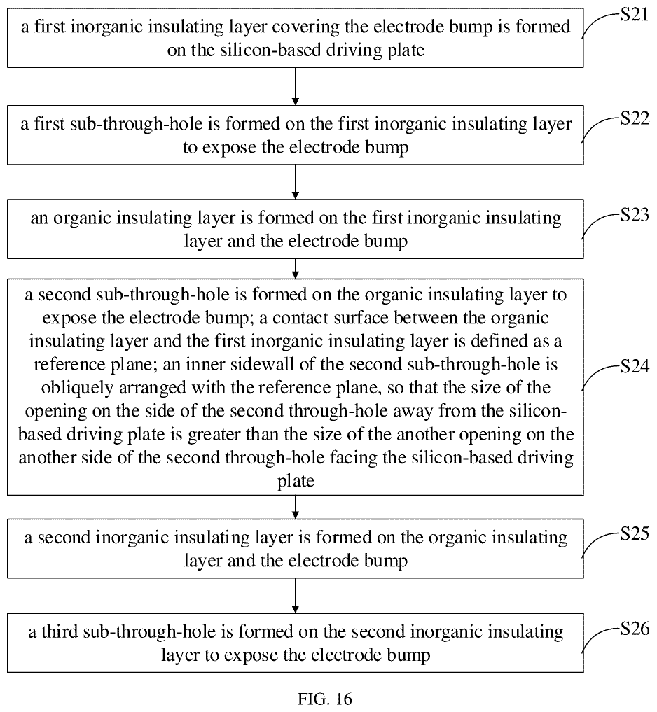

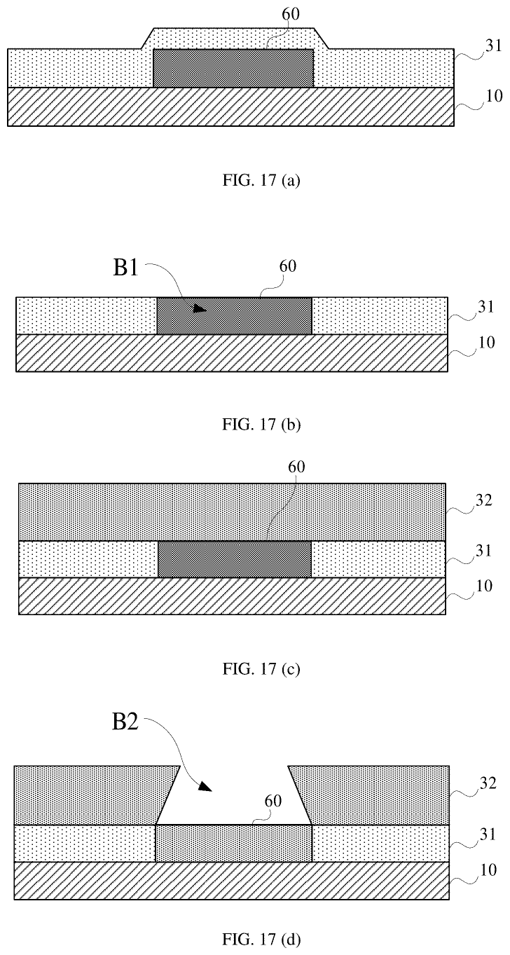

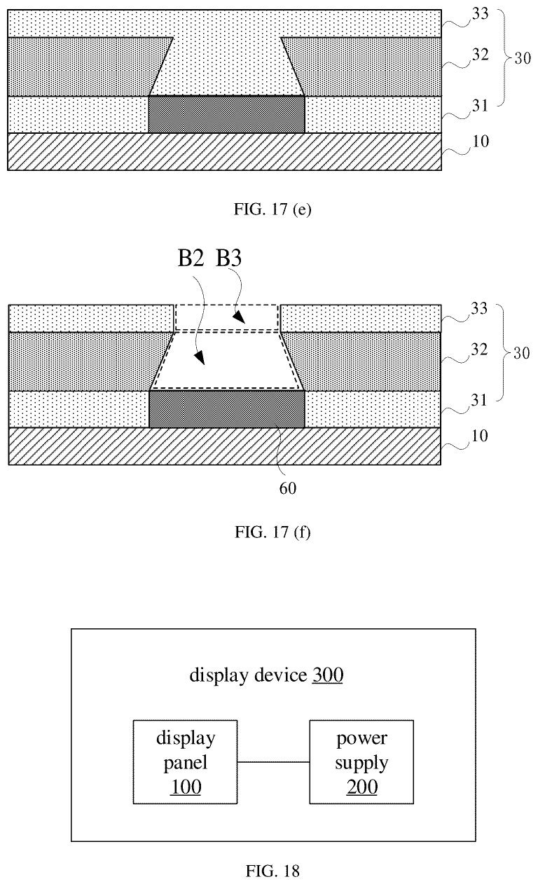

In some embodiments, the block S20, the dielectric layer 30 covering the electrode bump 60 being formed on the silicon-based driving plate 10 and the second through-hole B being formed on the dielectric layer 30 to expose the electrode bump 60 may include other sub operations. As shown in FIG. 16 and FIG. 17 (a) to FIG. 17 (f), FIG. 16 is a schematic flow chart of block S20 shown in FIG. 13, and FIG. 17 (a) to FIG. 17 (f) are schematic structural views corresponding to each block shown in FIG. 16. The block S20 may include sub operations executed by the following blocks.

At block S21, a first inorganic insulating layer 31 covering the electrode bump 60 is formed on the silicon-based driving plate 10.

As shown in FIG. 17 (a), a material of the first inorganic insulating layer 31 may include, but is not limited to SiNO-based materials, such as SiNx, SiO₂, or SixNO materials.

At block S22, a first sub-through-hole B1 is formed on the first inorganic insulating layer 31 to expose the electrode bump 60.

As shown in FIG. 17 (b), a first inorganic insulating layer 31 covering the electrode bump 60 is formed on the silicon-based driving plate 10, pattern process is performed by traditional methods such as exposure, etching, and development to form the first sub-through-hole B1 on the first inorganic insulating layer 31, and the electrode bump 60 is exposed.

At block S23, an organic insulating layer 32 is formed on the first inorganic insulating layer 31 and the electrode bump 60.

As shown in FIG. 17 (c), a material of the organic insulating layer 32 may include, but is not limited to, acrylic-type organic polymer materials.

At block S24, a second sub-through-hole B2 is formed on the organic insulating layer 32 to expose the electrode bump 60. A contact surface between the organic insulating layer 32 and the first inorganic insulating layer 31 is defined as a reference plane. An inner sidewall of the second sub-through-hole B2 is obliquely arranged with the reference plane, so that the size of the opening on the side of the second through-hole B away from the silicon-based driving plate 10 is greater than the size of the another opening on the another side of the second through-hole B facing the silicon-based driving plate 10.

As shown in FIG. 17 (d), in some embodiments, the organic insulating layer 32 is shaped into a film by nanoimprinting. That is, irregular-shaped structures such as smooth inverted triangles, rectangular serrations, triangular serrations, and circular serrations described in the above embodiments are formed.

In some embodiments, pixel defining layer (PDL) film formation is performed after the film layer of the first inorganic insulating layer 31 is manufactured, that is, the organic insulating layer 32 is formed above the first inorganic insulating layer 31. After the PDL film formation is completed, thermal nanoimprint lithography is performed using a patterned stamp of the desired shape. Demolding is performed after nanoimprint lithography. Specific reactive ions are then employed to etch away residual glue at the pattern edges, thereby completing the nanoimprint lithography of the specially shaped film layer.

Nanoimprint lithography completes the transfer of patterns through contact imprinting, which is equivalent to the exposure and development processed in optical lithography technology, and uses an etching transfer process to transfer the structure to other materials. The nanoimprint lithography overcomes the problem of the resolution limit caused by the optical diffraction phenomenon in optical lithography technology, and demonstrates unique advantages of ultra-high resolution, high efficiency, low cost, and suitability for industrial production. The latest overlay accuracy of nanoimprint lithography (NIL) has reached a circuit wire width of 5 nm. At present, three common nanoimprint technologies are hot embossing, ultraviolet imprinting, and compression molding. In this proposal, taking the hot embossing technology as an example, the preparation process of the isolation column will be illustrated. The imprinting material is a resin with high light transmittance, which is a common PDL organic resin.

At block S25, a second inorganic insulating layer 33 is formed on the organic insulating layer 32 and the electrode bump 60.

As shown in FIG. 17 (e), a material of the second inorganic insulating layer 33 is the same as the material of the first inorganic insulating layer 31.

At block S26, a third sub-through-hole B3 is formed on the second inorganic insulating layer 33 to expose the electrode bump 60.

As shown in FIG. 17 (f), after forming the second inorganic insulating layer 33 on the organic insulating layer 32 and the electrode bump 60, pattern process is performed by traditional methods such as exposure, etching, and development to form the third sub-through-hole B3 on the second inorganic insulating layer 33 to expose the electrode bump 60.

In some embodiments, the second sub-through-hole B2 being formed on the organic insulating layer 32 to expose the electrode bump 60, includes the second sub-through-hole B2 being formed on the organic insulating layer 32 and a recessed portion being formed on the inner sidewall of the second sub-through-hole B2 to expose the electrode bump 60. As shown in FIG. 8 to FIG. 10, the shape and number of the recessed portion are described in the above embodiments and will not be repeated here.

At block S30, the glass substrate 20 is bonded to the dielectric layer 30 so that the first through-hole A and the second through-hole B are communicated.

As shown in FIG. 1 and FIG. 4, the glass substrate 20 is bonded to the dielectric layer 30 so that a center of the first through-hole A and a center of the second through-hole B are aligned and communicated.

At block S40, a connecting portion 50 is filled in the first through-hole A and the second through-hole B.

As shown in FIG. 1 and FIG. 7, the connecting portion 50 is filled to electrically connect the organic light-emitting display component 40 with the electrode bump 60, enabling signal transmission. Considering the internal irregular-shaped structures, in some embodiments, the connecting portion 50 adopts a liquid filling method to ensure complete infiltration of the internal structures of the first through-hole A and the second through-hole B.

At block S50, an organic light-emitting display component 40 is formed on the glass substrate 20. The organic light-emitting display component 40 is bonded to the silicon-based driving plate 10 through the connecting portion 50 and the electrode bump 60.

After the above process, the manufacture of the silicon-based driving plate is completed. Subsequently, the through-holes are drilled on the glass substrate and filled with the conductive material. The conductive material may be deposited through inkjet printing or direct liquid filling methods. Given the complex internal irregular-shaped structures of the glass substrate, conventional PVD file deposition methods are unsuitable. Liquid-phase filling represents the optimal approach to ensure complete filling. After the conductive material is filled, subsequent manufacture processes on the glass substrate may be carried out.

As shown in FIG. 18, FIG. 18 is a schematic structural view of a display device according to some embodiments of the present disclosure. The display device 300 includes a display panel 100 and a power supply 200. The power supply 200 is configured to supply power to the display panel 100. The display panel 100 is the display panel 100 described in any of the above embodiments, or the display panel 100 is manufactured by a manufacturing method of the display panel 100 described in any of the above embodiments.

In some application scenarios, the display device 300 is applied to a miniature display, such as an AR/VR device.

The present disclosure provides the display panel 100. The display panel 100 includes the silicon-based driving plate 10, the glass substrate 20, the dielectric layer 30, and the organic light-emitting display component 40. The glass substrate 20 is arranged on the side of the silicon-based driving plate 10, and the glass substrate 20 is defined with the first through-hole A. The dielectric layer 30 is arranged between the silicon-based driving plate 10 and the glass substrate 20, and the dielectric layer 30 is defined with the second through-hole B. The size of the opening on the side of the second through-hole B facing the silicon-based driving plate 10 is greater than the size of the another opening on the another side of the second through-hole B facing the glass substrate 20. The organic light-emitting display component 40 is arranged on the side of the glass substrate 20 away from the silicon-based driving plate 10. The organic light-emitting display component 40 is bonded to the silicon-based driving plate 10 through the connecting portion 50 filled in the first through-hole A and the second through-hole B.

In this way, on the one hand, by arranging the dielectric layer 30 and setting an inner portion of the organic insulating layer 32 in the middle of the dielectric layer 30 to an irregular-shaped structure, a surface area inside the organic insulating layer 32 is increased; on the other hand, by filling a conductive material in the first through-hole A and the second through-hole B, the organic light-emitting display component 40 is bonded to the silicon-based driving plate 10, and a contact area with a film layer of the lower silicon-based driving plate 10 is increased. Furthermore, if relative displacement occurs between the silicon-based driving plate 10 and the glass substrate 20, the conductive material bonding the silicon-based driving plate 10 and the glass substrate 20 may experience increased frictional resistance due to its interlocking fit with the irregular-shaped structure. This effectively prevents displacement and deformation of the conductive material, as well as issues such as film layer fracture and delamination caused by external forces. In this way, the structure and shape of the insulation layer above the silicon substrate are designed to modify the filling shape of the conductive material, potential connection failures may be prevented if the two-layer structure of the silicon-based driving plate 10 and the glass substrate 20 undergoes deformation, thereby significantly improving the stability of signal transmission through the through-holes and ultimately improving the display quality of the product.

In some embodiments provided in the present disclosure, it should be understood that the methods and device disclosed mat be achieved by other means. For example, the device embodiments described above are only schematic, for example, the division of the module or unit is only a logical function division, and the actual implementation may have another division mode, such as multiple units or components may be combined or may be integrated into another system, or some features may be ignored, or not executed.

The unit described as a detached part may or may not be physically separated, and the part displayed as a unit may or may not be a physical unit, that is, may be located in one place, or may also be distributed on multiple network units. Some or all of the units may be selected according to actual requirements to achieve the purpose of the embodiments.

In addition, each functional unit in each embodiment of the present disclosure may be integrated into a processing unit, or each unit may physically exist separately, or two or more units may be integrated into a single unit. The above-mentioned integrated units may be implemented either in the form of hardware or in the form of software function units.

The foregoing is only embodiments of the present disclosure, and does not limit the scope of the patent of the present disclosure. Any equivalent structural or equivalent process modifications made by using the contents of the description and drawings of the present disclosure, or directly or indirectly applied to other related technical fields, are similarly fall within the scope of patent protection of the present disclosure.

1. A display panel, comprising:
a silicon-based driving plate;
a glass substrate, arranged on a side of the silicon-based driving plate, wherein the glass substrate has a first through-hole defined therein;
a dielectric layer, arranged between the silicon-based driving plate and the glass substrate, wherein the dielectric layer has a second through-hole defined therein, a size of an opening on a side of the second through-hole facing the silicon-based driving plate is greater than a size of another opening on another side of the second through-hole facing the glass substrate;
an organic light-emitting display component, arranged on a side of the glass substrate away from the silicon-based driving plate, wherein the organic light-emitting display component is bonded to the silicon-based driving plate through a connecting portion filled in the first through-hole and the second through-hole.

2. The display panel according to claim 1, wherein the dielectric layer comprises:
a first inorganic insulating layer, arranged on a side of the silicon-based driving plate facing the glass substrate, wherein the first inorganic insulating layer has a first sub-through-hole defined therein;
an organic insulating layer, arranged on a side of the first inorganic insulating layer facing the glass substrate, wherein the organic insulating layer has a second sub-through-hole defined therein;
a second inorganic insulating layer, arranged on a side of the organic insulating layer facing the glass substrate, wherein the second inorganic insulating layer has a third sub-through-hole defined therein;
wherein the first sub-through-hole, the second sub-through-hole, and the third sub-through-hole are communicated in sequence to form the second through-hole.

3. The display panel according to claim 2, wherein a contact surface between the organic insulating layer and the first inorganic insulating layer is defined as a reference plane, and an inner sidewall of the second sub-through-hole is obliquely arranged with the reference plane, so that a size of an opening on a side of the second sub-through-hole of the organic insulating layer facing the first inorganic insulating layer is greater than a size of another opening on another side of the second sub-through-hole facing the second inorganic insulating layer.

4. The display panel according to claim 3, wherein an angle between the inner sidewall of the second sub-through-hole and the reference plane is in a range of 30 degrees to 75 degrees.

5. The display panel according to claim 2, wherein an electrode bump is arranged on the side of the silicon-based driving plate facing the glass substrate, the electrode bump is accommodated in the first sub-through-hole, and the organic light-emitting display component is bonded to the silicon-based driving plate through a connecting portion filled in the first through-hole, the second sub-through-hole, and the third sub-through-hole, and the electrode bump.

6. The display panel according to claim 5, wherein the silicon-based driving plate comprises:
a silicon substrate;
a plurality of driving components, arranged on a side of the silicon substrate facing the glass substrate;
a protective layer, covering the driving components and defined with a plurality of third through-holes, wherein a number of the electrode bump is more than one, and each electrode bump is connected to a corresponding one of the plurality of driving components through a corresponding one of the plurality of third through-holes.

7. The display panel according to claim 5, wherein the organic light-emitting display component comprises:
an isolation structure, arranged on a side of the glass substrate away from the silicon-based driving plate, and defined with a plurality of pixel openings;
a plurality of sub-pixels, each arranged in a corresponding one of the plurality of pixel openings.

8. The display panel according to claim 7, wherein a number of the first through-hole is more than one, a number of the second through-hole is more than one, and a number of the electrode bump is more than one;
wherein each of the plurality of sub-pixels comprises:
a first electrode, arranged on the side of the glass substrate away from the silicon-based driving plate, and connected with a corresponding electrode bump through a corresponding first through-hole;
a light-emitting component, arranged on a side of the first electrode away from the glass substrate;
a second electrode, arranged on a side of the light-emitting component away from the first electrode, and connected to at least one electrode bump through at least one first through-hole and at least one second through-hole.

9. The display panel according to claim 8, wherein the isolation structure is defined with a plurality of fourth through-holes, each of the plurality of fourth through-holes is communicated with a corresponding first through-hole, and the second electrode is connected with a corresponding electrode bump through one of the plurality of fourth through-holes, the corresponding first through-hole, and a corresponding second through-hole.

10. The display panel according to claim 2, wherein a recessed portion is defined on the inner sidewall of the second sub-through-hole, a protruding portion is arranged on an outer sidewall of the connecting portion, and the protruding portion is embedded in the recessed portion.

11. The display panel according to claim 2, wherein a diameter of an opening on a side of the second sub-through-hole facing the glass substrate is equal to or slightly less than a diameter of the first through-hole.

12. The display panel according to claim 2, wherein a diameter of the third sub-through-hole is equal to a diameter of the first through-hole, and the diameter of the third sub-through-hole is greater than or equal to a diameter of an opening on a side of the second sub-through-hole facing the glass substrate.

13. A manufacturing method of a display panel, comprising:
providing a silicon-based driving plate and a glass substrate, wherein a side of the silicon-based driving plate is arranged with an electrode bump and the glass substrate is defined with a first through-hole;
forming a dielectric layer covering the electrode bump on the silicon-based driving plate and forming a second through-hole on the dielectric layer to expose the electrode bump, wherein a size of an opening on a side of the second through-hole away from the silicon-based driving plate is greater than a size of another opening on another side of the second through-hole facing the silicon-based driving plate;
bonding the glass substrate to the dielectric layer so that the first through-hole and the second through-hole are communicated;
filling a connecting portion in the first through-hole and the second through-hole;
forming an organic light-emitting display component on the glass substrate, wherein the organic light-emitting display component is bonded to the silicon-based driving plate through the connecting portion and the electrode bump.

14. The manufacturing method of a display panel according to claim 13, wherein the forming a dielectric layer covering the electrode bump on the silicon-based driving plate and forming a second through-hole on the dielectric layer to expose the electrode bump, comprises:
forming a first inorganic insulating layer covering the electrode bump on the silicon-based driving plate;
forming a first sub-through-hole on the first inorganic insulating layer to expose the electrode bump;
forming an organic insulating layer on the first inorganic insulating layer and the electrode bump;
forming a second sub-through-hole on the organic insulating layer to expose the electrode bump, wherein a contact surface between the organic insulating layer and the first inorganic insulating layer is defined as a reference plane, and an inner sidewall of the second sub-through-hole is obliquely arranged with the reference plane, so that the size of the opening on the side of the second through-hole away from the silicon-based driving plate is greater than the size of the another opening on the another side of the second through-hole facing the silicon-based driving plate;
forming a second inorganic insulating layer on the organic insulating layer and the electrode bump;
forming a third sub-through-hole on the second inorganic insulating layer to expose the electrode bump.

15. The manufacturing method of a display panel according to claim 14, wherein the forming a second sub-through-hole on the organic insulating layer to expose the electrode bump, comprises:
forming the second sub-through-hole on the organic insulating layer and forming a recessed portion on the inner sidewall of the second sub-through-hole to expose the electrode bump.

16. The manufacturing method of a display panel according to claim 13, wherein the providing a silicon-based driving plate and a glass substrate, comprises:
providing a silicon substrate;
forming a plurality of driving components on a side of the silicon substrate;
forming a protective layer on a side of the driving components away from the silicon substrate to cover the driving components;
performing a patterning process on the protective layer to form a plurality of third through-holes on the protective layer;
forming a plurality electrode bumps on a side of the protective layer away from the driving components, wherein each of the plurality of electrode bumps is connected to a corresponding one of the plurality of driving components through a corresponding one of the plurality of third through-holes.

17. A display device, comprising:
a display panel, wherein the display panel comprises:
a silicon-based driving plate;
a glass substrate, arranged on a side of the silicon-based driving plate, wherein the glass substrate has a first through-hole defined therein;
a dielectric layer, arranged between the silicon-based driving plate and the glass substrate, wherein the dielectric layer has a second through-hole defined therein, a size of an opening on a side of the second through-hole facing the silicon-based driving plate is greater than a size of another opening on another side of the second through-hole facing the glass substrate;
an organic light-emitting display component, arranged on a side of the glass substrate away from the silicon-based driving plate, wherein the organic light-emitting display component is bonded to the silicon-based driving plate through a connecting portion filled in the first through-hole and the second through-hole; or
the display panel is manufactured by a manufacturing method comprising:
providing a silicon-based driving plate and a glass substrate, wherein a side of the silicon-based driving plate is arranged with an electrode bump and the glass substrate is defined with a first through-hole;
forming a dielectric layer covering the electrode bump on the silicon-based driving plate and forming a second through-hole on the dielectric layer to expose the electrode bump, wherein a size of an opening on a side of the second through-hole away from the silicon-based driving plate is greater than a size of another opening on another side of the second through-hole facing the silicon-based driving plate;
bonding the glass substrate to the dielectric layer so that the first through-hole and the second through-hole are communicated;
filling a connecting portion in the first through-hole and the second through-hole;
forming an organic light-emitting display component on the glass substrate, wherein the organic light-emitting display component is bonded to the silicon-based driving plate through the connecting portion and the electrode bump; and
a power supply, configured for supplying power to the display panel.

18. The display device according to claim 17, wherein the dielectric layer comprises:
a first inorganic insulating layer, arranged on a side of the silicon-based driving plate facing the glass substrate, wherein the first inorganic insulating layer has a first sub-through-hole defined therein;
an organic insulating layer, arranged on a side of the first inorganic insulating layer facing the glass substrate, wherein the organic insulating layer has a second sub-through-hole defined therein;
a second inorganic insulating layer, arranged on a side of the organic insulating layer facing the glass substrate, wherein the second inorganic insulating layer has a third sub-through-hole defined therein;
wherein the first sub-through-hole, the second sub-through-hole, and the third sub-through-hole are communicated in sequence to form the second through-hole.

19. The display device according to claim 18, wherein a contact surface between the organic insulating layer and the first inorganic insulating layer is defined as a reference plane, and an inner sidewall of the second sub-through-hole is obliquely arranged with the reference plane, so that a size of an opening on a side of the second sub-through-hole of the organic insulating layer facing the first inorganic insulating layer is greater than a size of another opening on another side of the second sub-through-hole facing the second inorganic insulating layer.

20. The display device according to claim 18, wherein an electrode bump is arranged on the side of the silicon-based driving plate facing the glass substrate, the electrode bump is accommodated in the first sub-through-hole, and the organic light-emitting display component is bonded to the silicon-based driving plate through a connecting portion filled in the first through-hole, the second sub-through-hole, and the third sub-through-hole, and the electrode bump.
